(19) United States
(12) Patent Application Publication
(10) Pub. No.: US 2004/0088612 A1
(43) Pub. Date: May 6, 2004

(54) Redundancy circuit of semiconductor memory device and fail repair method using the same

(76) Inventor: Jin-Yong Seong, Ichon-shi (KR)

Correspondence Address: BIRCH STEWART KOLASCH & BIRCH, PO BOX 747, FALLS CHURCH, VA, 22040-0747, US

(21) Appl. No.: 10/330,249

(22) Filed: Dec. 30, 2002

(30) Foreign Application Priority Data
Oct. 31, 2002 (KR) 2002-67116

(51) Int. Cl. G11C 29/00

(52) U.S. Cl. 714/710

(57) ABSTRACT

There are provided a redundancy circuit of a semiconductor memory device and a fail repair method, which are capable of repairing both a fail main cell and a fail redundancy cell when the redundancy cell substituted for the fail main cell is defective. The redundancy circuit includes: a repair logic unit 100 for replacing a logic unit related to a memory cell array unit; a first programming unit 110 for connecting a redundancy cell array unit 120 with the repair logic unit 100 by programming to replace a main cell having a fail bit with a redundancy cell; a second programming unit 130 for connecting a repair redundancy cell array unit 140 with the repair logic unit 100 by programming to replace a redundancy cell having a fail bit with a repair cell; a redundancy cell array unit 120 having a plurality of redundancy cells substituted for the fail cells by the programming state of the first programming unit 110; and a repair redundancy cell array unit 140 having a plurality of repair redundancy cells substituted for the fail redundancy cell by the programming state of the second programming unit 130. The first programming unit 110 includes fuses and the second programming unit 130 includes ferroelectric capacitors.

### FIELD OF THE INVENTION

The present invention relates to a semiconductor device and, more particularly, to a redundancy circuit of a semiconductor memory device and a repair method using the same.

Description of the prior Art

With high integration of a semiconductor memory device, more semiconductor memory cells are integrated into one chip. If there is a failure in any one of these memory cells, corresponding semiconductor memory chip is classified as a defective product so that it is not used. Like this, in case where even one cell is defective, if the entire memory chip is classified as a defective product, a probability that memory chips are classified as defective products is increased with an increase of integration of a memory device. Additionally, it is impossible to produce semiconductor memory chips having an actually economical efficiency. Accordingly, as is well known, a redundancy circuit is employed in order to solve these problems.

Generally, for the purpose of increasing yield in a design for manufacturing a semiconductor device, a redundancy circuit is added when designing a memory device in order to replace defective devices or circuits. The redundancy circuit includes extra rows and columns formed adjacent to a memory cell array. If defective memory cells occur, row and column constituting the defective circuit are replaced with the extra row and column.

The replacement of these defective memory cells is achieved by selectively blowing fuses formed in the memory device. Generally, the fuse is formed of polysilicon layer and blown by flowing an excessive current or irradiating a laser beam.

FIG. 1 is a flowchart showing a conventional fail repair method. Referring to FIG. 1, in step S1, a chip test is carried out. In step S2, a fail bit is analyzed and a fail address is found. In steps S3 and S4, if the fail address is determined, corresponding fuse is cut so as to repair corresponding memory cell address using a redundancy algorithm.

In step S5, after the repair is completed, a reconfirmation chip test is carried out to check whether or not it is normal.

FIG. 2 shows a concept of a conventional fail repair. Referring to FIG. 2, there are a main cell array MCA and a redundancy cell array RCA and fail cells FC(0) to FC(n) are directly repaired by the redundancy cells.

FIG. 3 is a block diagram showing a conventional redundancy circuit.

Referring to FIG. 3, the conventional redundancy circuit includes a fuse block 12, a redundancy cell array block 13 and a redundancy control unit 11. The redundancy cell array block 13 and corresponding fuse block 12 are formed in advance when manufacturing the semiconductor device, and corresponding fuse block 12 is programmed so as to replace defective main cell with the redundancy cell in the test step. Such a programming operation is called a “repair” and is carried out by selectively blowing the fuse of the fuse block 12, which is provided between the redundancy control unit 11 and the redundancy cell array block 13, using a laser beam.

In the repair operation of the memory device through the redundancy circuit of FIG. 3, the redundancy cell array block is formed and it is tested whether or not the main cell array block is defective. Then, among the main cell array blocks, the main cells determined as a fail bit is replaced with the redundancy cell of the redundancy cell array blocks.

If an address accessing to the main cell having the fail bit is applied, the redundancy circuit is operated and the replaced redundancy cell array block is accessed, so that the memory device is normally operated without any error.

In the prior art, in order to repair the main cell having the fail cell, a repair mask and etch is carried out to a wafer proceeding to a process of passivation.

FIG. 4 is a cross-sectional diagram showing a conventional repair etch method.

Referring to FIG. 4, a fuse 15 formed of a polysilicon layer is formed on a semiconductor substrate 14, and an intermediate insulating layer 16 is formed on an entire surface containing a fuse line. Then, a metal pad 17 is formed on the intermediate insulating layer 16. At this time, the metal pad 17 is not overlapped with the fuse 15. A passivation layer 18 is formed on an entire surface containing the metal pad 17. Then, a repair etch for remaining the intermediate insulating layer 16 on an upper portion of the fuse 15 and a pad etch process for exposing the metal pad 17 are carried out.

In FIG. 4, a laser beam irradiated to the fuse 15 and the fuse 15 is blown, so that the repair operation is achieved.

Following conditions are required in the repair etch method of FIG. 4.

First, in order for an easiness of the interconnection process during the repair etch process, the upper-most metal pad 17 must be exposed. Second, in order for an easiness of the laser repair process for replacing the main cell having the fail bit with the redundancy cell after the wafer test, an oxide layer must be remained on the fuse 15 at a predetermined thickness by etching the passivation layer 18.

However, a failure may also occur in the redundancy cell substituted for the fail cell. In this case, since the memory device is not repaired due to the fail redundancy cell, a fail state is maintained and the memory device is operated abnormally.

Accordingly, there is demanded a method for replacing the fail redundancy cell with other redundancy cell in order to improve the yield of the memory device.

### SUMMARY OF THE INVENTION

It is, therefore, an object of the present invention to provide a redundancy circuit of a semiconductor memory device and a fail repair method using the same.

In a semiconductor memory device including a memory cell array provided with a plurality of main cells and a redundancy circuit for replacing main cells having fail bits with redundancy cells, the redundancy circuit in accordance with the present invention comprises: a redundancy cell array including a plurality of redundancy cells to be substituted for the main cell having the fail bit; and a repair redundancy cell array including a plurality of repair redundancy cells to be substituted for the redundancy cell having the fail bit, if the fail bit occurs in the redundancy cell substituted for the main cell having the fail bit. The redundancy circuit further comprises: a repair logic unit for replacing a logic unit related to the memory cell array; a first programming unit for connecting the redundancy cell array unit with the repair logic unit by programming to replace the main cell having the fail bit with the redundancy cell; and a second programming unit for connecting the repair redundancy cell array with the repair logic unit by programming to replace the redundancy cell having the fail bit with the repair redundancy cell.

In a semiconductor memory device including a memory cell array provided with a plurality of main cells, there is provided a fail repair method for replacing main cells having fail bits with redundancy cells, which comprises the steps of: replacing the main cell having the fail bit with the redundancy cell by a fuse cutting; and if the fail bit occurs in the redundancy cell substituted for the main cell having the fail bit, replacing the redundancy cell having a fail bit with a repair redundancy cell by shorting two electrodes of a ferroelectric capacitor. The shorting of the two electrodes of the ferroelectric capacitor is carried out by applying an electric forcing upon conditions that a ferroelectric layer of the ferroelectric capacitor is broken down.

### BRIEF DESCRIPTION OF THE DRAWINGS

Other objects and aspects of the invention will become apparent from the following description of the embodiments with reference to the accompanying drawings, in which:

FIG. 1 is a flowchart showing a conventional fail repair method;

FIG. 2 shows a concept of a conventional fail repair;

FIG. 3 is a block diagram showing a conventional redundancy circuit;

FIG. 4 is a cross-sectional diagram showing a conventional repair etch method;

FIG. 5 illustrates a characteristic of a ferroelectric capacitor used in the present invention;

FIG. 6 is a flowchart illustrating a fail repair method in accordance with the present invention;

FIG. 7 illustrates a concept of a fail repair in accordance with an embodiment of the present invention;

FIG. 8 illustrates a configuration of a redundancy circuit of a semiconductor memory device in accordance with an embodiment of the present invention;

FIG. 9 illustrates a circuit for shorting a ferroelectric capacitor;

FIG. 10 is a circuit diagram of the second programming unit shown in FIG. 9; and

FIG. 11 is a cross-sectional diagram of the ferroelectric capacitor in a state that an electric forcing is applied thereto.

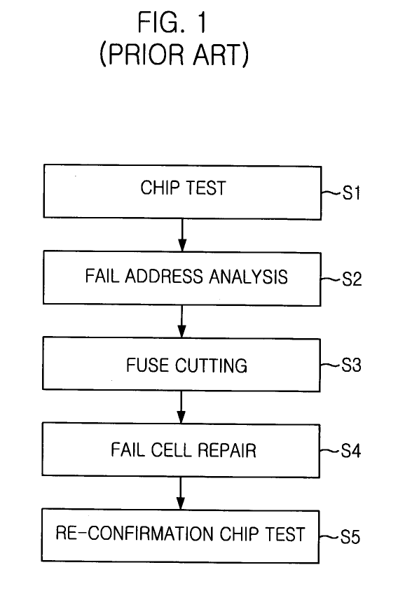

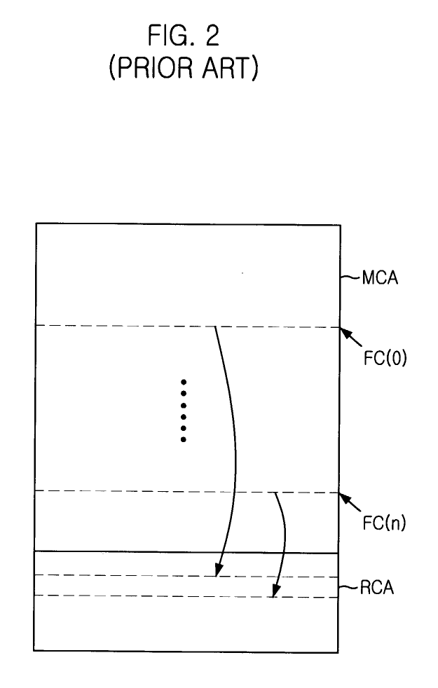

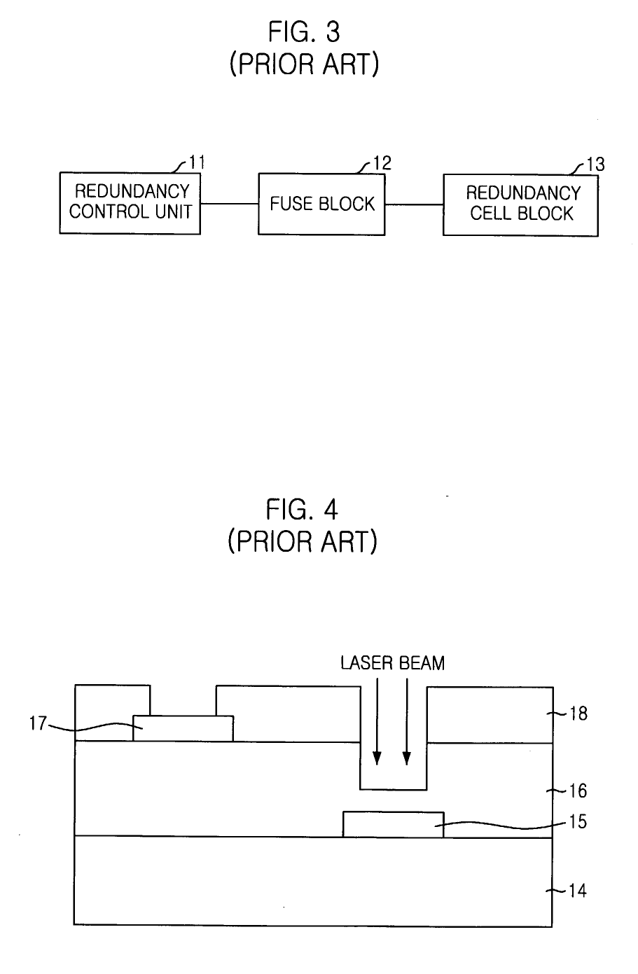

### DETAILED DESCRIPTION OF THE PREFERRED EMBODIMENTS

Hereinafter, preferred embodiments of the present invention will be descried in detail with reference to attached drawings.

The present invention proposes a semiconductor memory device capable of repairing a fail redundancy cell as well as a fail memory cell, if there occurs a failure in the redundancy cell substituted for the main cell having a fail bit.

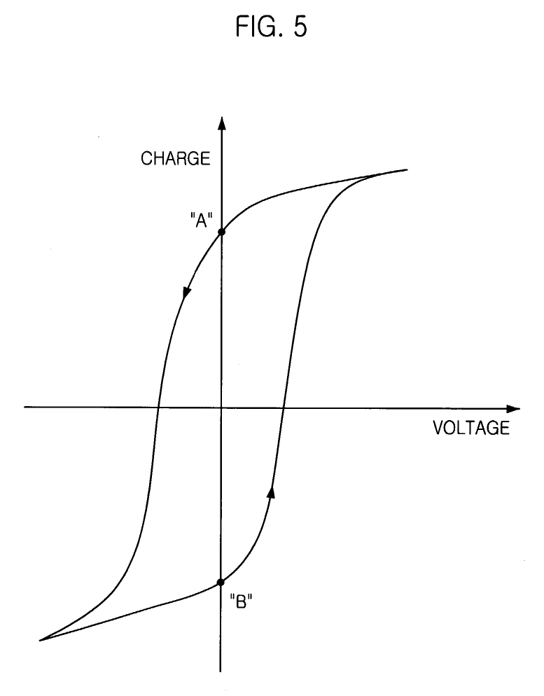

FIG. 5 illustrates a characteristic of a ferroelectric capacitor used in the present invention. The ferroelectric capacitor has a hysteresis characteristic and maintains any one of an “A” state and a “B” state even when an applied external voltage is “0” V. A redundancy circuit in accordance with the present invention is configured using these nonvolatile characteristic of the ferroelectric capacitor (FC).

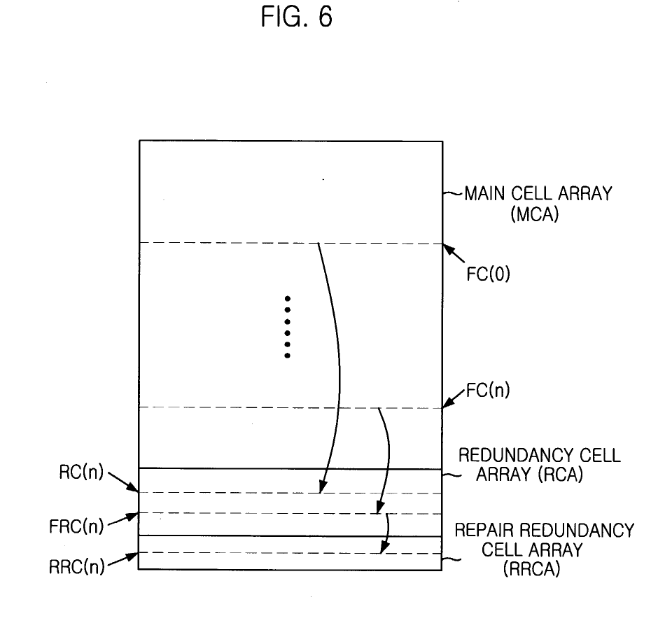

FIG. 6 is a flowchart illustrating a fail repair method in accordance with the present invention.

Referring to FIG. 6, in steps S11 and S12, a chip test is carried out and a fail bit is analyzed to find a fail address. In steps S13 and S14, if the fail address is determined, corresponding fuse is cut so as to repair corresponding memory cell address using a redundancy algorithm, thereby repairing the fail cell.

In steps S15 and S16, after completing the repair, a reconfirmation chip test is carried out to check whether or not it is normal, and it is analyzed whether or not the redundancy cell for repairing the fail cell is a fail cell.

In step S17, if the redundancy cell is determined as the fail cell, the corresponding fuse is cut and the corresponding redundancy cell is not used. The ferroelectric capacitor is shorted.

In step S18, by shorting the ferroelectric capacitor, the fail cell and the redundancy cell are replaced with a repair redundancy cell.

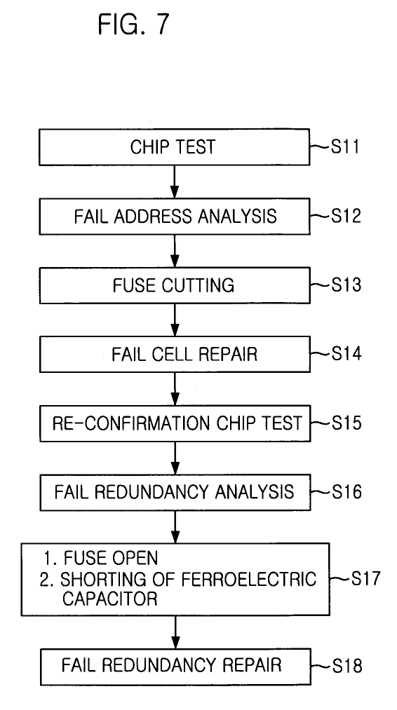

FIG. 7 illustrates a concept of the fail repair in accordance with an embodiment of the present invention. The fail repair is provided with a main cell array unit (MCA), a redundancy cell array unit (RCA) for repairing the fail cells, and a repair redundancy cell array unit (RRCA), in substitute of the fail redundancy cell, for repair the fail cells. The fail cells FC(0) to FC(n) are directly repaired by the redundancy cells RC(n) and the fail redundancy cells FRC(0) to FRC(n) are directly repaired by the repair redundancy cells RRC(n).

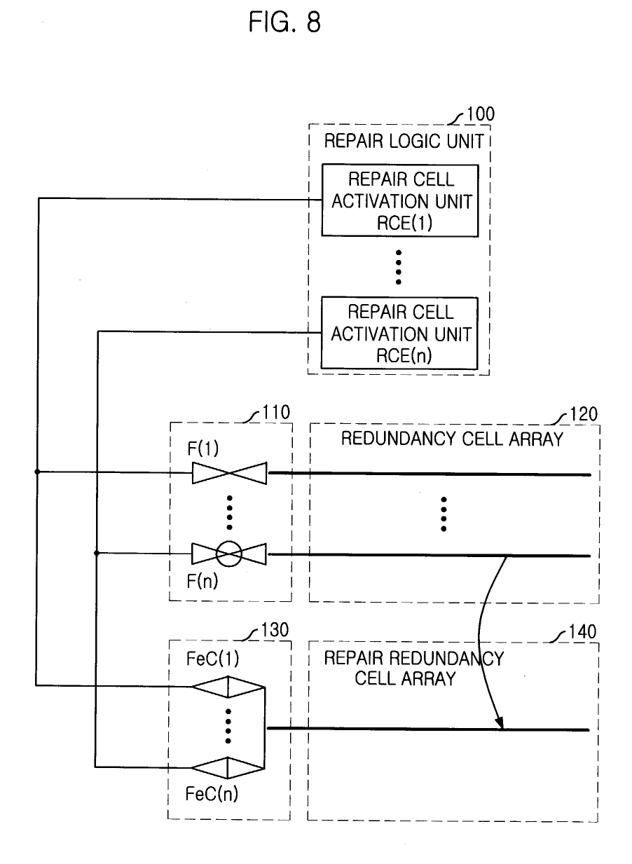

FIG. 8 illustrates a configuration of the redundancy circuit of a semiconductor memory device in accordance with an embodiment of the present invention.

Referring to FIG. 8, the redundancy circuit in accordance with the present invention includes: a repair logic unit 100 for replacing a logic unit related to a memory cell array unit; a first programming unit 110 for connecting a redundancy cell array unit 120 with the repair logic unit 100 by programming to replace a main cell having a fail bit with a redundancy cell; a second programming unit 130 for connecting a repair redundancy cell array unit 140 with the repair logic unit 100 by programming to replace a redundancy cell having a fail bit with a repair cell; a redundancy cell array unit 120 having a plurality of redundancy cells substituted for the fail cells by the programming state of the first programming unit 110; and a repair redundancy cell array unit 140 having a plurality of repair redundancy cells substituted for the fail redundancy cell by the programming state of the second programming unit 130.

Specifically, the repair logic unit 100 includes a plurality of repair cell activation units RCE(1) to RCE(n) corresponding to rows/columns. These repair cell activation units RCE(1) to RCE(n) have the same structures as the logic unit related to the main cell, e.g., a sense amplifier and a data bus. The repair cell activation units RCE(1) to RCE(n) are logic circuits for controlling the redundancy cell or the repair redundancy cells in the same manner as the main cells.

The first programming unit 110 includes a plurality of fuses F(1) to F(n) connected with respective rows/columns of the redundancy cell array unit 120. The respective fuses F(1) to F(n) are connected with the respective repair cell activation units RCE(L) to RCE(n).

The second programming unit 130 includes a plurality of ferroelectric capacitors FeC(1) to FeC(n) connected with the respective rows/columns of the repair redundancy cell array unit 140. The ferroelectric capacitors are connected with the respective repair cell activation units RCE(1) to RCE(n).

In other words, the rows/columns of the repair redundancy cell array unit are connected with one end of the ferroelectric capacitors FeC(1) to FeC(n), and the repair cell activation units RCE(1) to RCE(n) are connected with the other end of the ferroelectric capacitors FeC(1) to FeC(n).

In FIG. 8, the redundancy circuit of the present invention further includes the repair redundancy cells for repairing the redundancy cells and thus is a “dual redundancy circuit”.

In the operation of the redundancy circuit, if a fail occurs in n-th main cell, a fuse F(n) connected to n-th row/column of the redundancy cell array unit 120 is cut using a laser, so that the fail cell is repaired.

As a result of the chip test, if a fail occurs in the n-th redundancy cell for repairing the fail cell, the fuse F(n) connected to n-th row/column of the redundancy cell array unit 120 is cut and opened using the laser, and n-th ferroelectric capacitor FeC(n) of the repair redundancy cell array unit 140 is shorted, so that n-th redundancy cell activation unit RCE(n) is connected to the repair redundancy cell array unit 140.

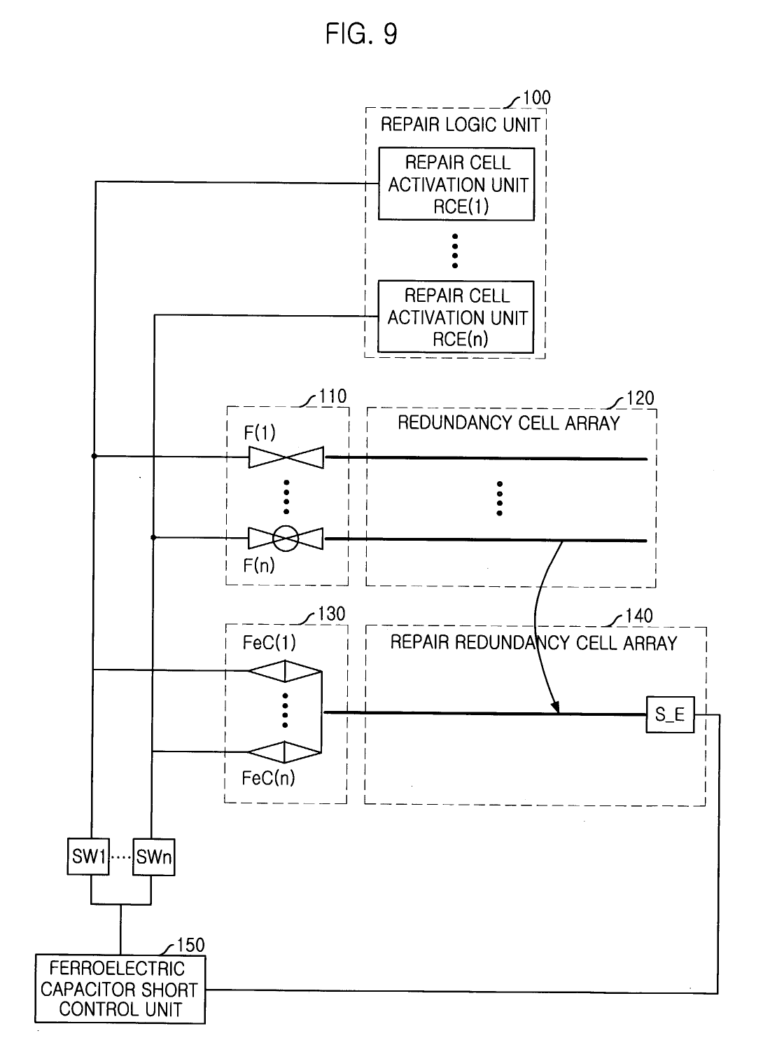

FIG. 9 illustrates a circuit for shorting the ferroelectric capacitor.

Referring to FIG. 9, the circuit for shorting the ferroelectric capacitor includes: a repair logic unit 100 for replacing a logic unit related to memory cells; a first programming unit 110 for connecting a redundancy cell array unit 120 with the repair logic unit 100 by programming to replace a main cell having a fail bit with a redundancy cell; a second programming unit 130 for connecting a repair redundancy cell array unit 140 with the repair logic unit 100 by programming to replace a redundancy cell having a fail bit with a repair cell; a redundancy cell array unit 120 having a plurality of redundancy cells substituted for the fail cells by the programming state of the first programming unit 110; a repair redundancy cell array unit 140 having a plurality of repair redundancy cells substituted for the fail redundancy cell by the programming state of the second programming unit 130; and a ferroelectric capacitor short control unit 150 for shorting the ferroelectric capacitor of the second programming unit 130.

Specifically, the repair logic unit 100 includes a plurality of repair cell activation units RCE(1) to RCE(n) corresponding to rows/columns. These repair cell activation units RCE(1) to RCE(n) have the same structures as the logic unit related to the main cell, e.g., a sense amplifier and a data bus. The repair cell activation units RCE(1) to RCE(n) are logic circuits for controlling the redundancy cell or the repair redundancy cells in the same manner as the main cells.

The first programming unit 110 includes a plurality of fuses F(1) to F(n) connected with respective rows/columns of the redundancy cell array unit 120. The respective fuses F(1) to F(n) are connected with the respective repair cell activation units RCE(1) to RCE(n).

The second programming unit 130 includes a plurality of ferroelectric capacitors FeC(1) to FeC(n) connected with the respective rows/columns of the repair redundancy cell array unit 140. The ferroelectric capacitors are connected with the respective repair cell activation units RCE(1) to RCE(n).

The ferroelectric capacitor short control unit 150 is connected to the respective ferroelectric capacitors FeC(1) via switches SW1 to SWn, and the rows/columns of the repair redundancy cell array unit 140 are connected to another control terminal of the ferroelectric capacitor short control unit 150 via an activation switch S_E.

An operation of shorting the ferroelectric capacitor will be described with reference to FIG. 9. If n-th ferroelectric capacitor FeC(n) is shorted, the activation switch S_E and the n-th switch SWn are simultaneously switched on so that the ferroelectric capacitor short control unit 150 and the n-th ferroelectric capacitor FeC(n) are connected to each other and the ferroelectric capacitor short control unit 150 and the row/column of the repair redundancy cell array unit 140 are connected to each other, respectively. Then, by applying a high voltage higher than a critical voltage, an insulation of a ferroelectric layer of the n-th ferroelectric capacitor FeC(n) is broken down, so that two electrodes of the ferroelectric capacitor are shorted.

Accordingly, one of the n ferroelectric capacitors is shorted and the other ferroelectric capacitors are opened, thereby repairing the redundancy cell by the repair redundancy cell.

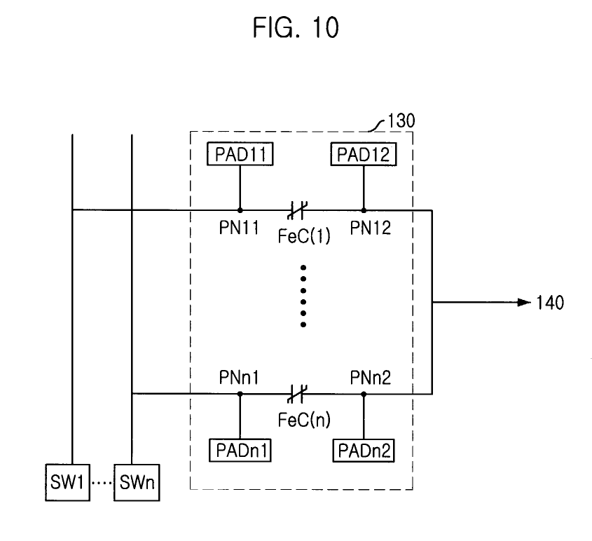

FIG. 10 is a circuit diagram of the second programming unit shown in FIG. 9.

Referring to FIG. 10, the second programming unit 130 includes: first and second program pads PAD11 to PADn1 and PAD12 to PADn2 for applying an electric forcing via first and second program nodes PN11 to PNn1 and PN12 to PNn2; and ferroelectric capacitors FeC(1) to FeC(n) whose two electrodes are respectively connected between the first program nodes PN11 to PNn1 and the second program nodes PN21 to PNn2 and shorted according to an applying of the high voltage higher than the critical voltage.

Here, the electric forcing is applied to the first and second program pads PADn1 and PADn2 connected to the both terminals of the ferroelectric capacitor upon conditions that the ferroelectric layer is broken down, and thus two electrodes of the ferroelectric capacitor are shorten to thereby form current path, thereby achieving the programming of the ferroelectric capacitor FeC for replacing the redundancy cells with the repair redundancy cells.

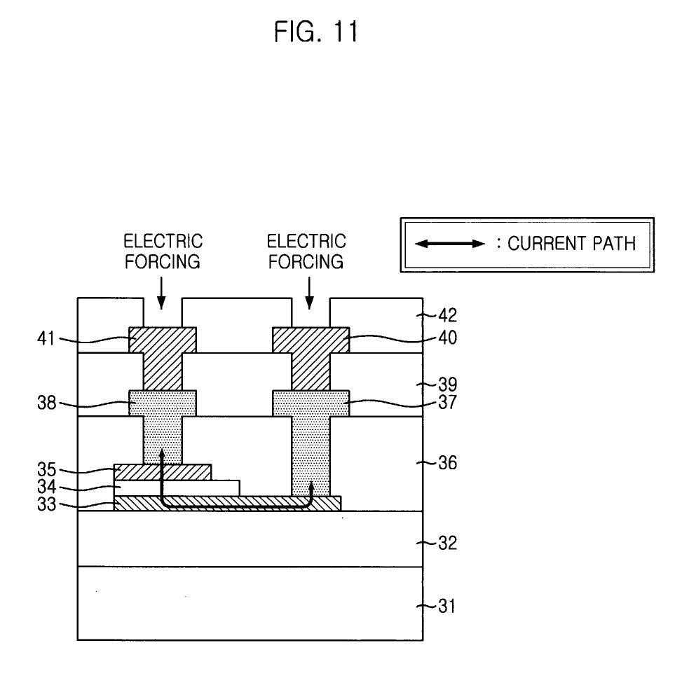

FIG. 11 is a cross-sectional diagram of the ferroelectric capacitor in a state that the electric forcing is applied thereto.

Referring to FIG. 11, a first intermediate insulating layer 32 is formed on a semiconductor substrate 31, and a ferroelectric capacitor FeC is formed on a predetermined surface of the first intermediate insulating layer 32 by sequentially forming a first electrode 33, a ferroelectric layer 34 and a second electrode 35.

A second intermediate insulating layer 36 covering an upper portion of the ferroelectric capacitor is formed, and a first program node 37 passing through one side of the second intermediate insulating layer 36 is connected to the first electrode 33. A second program node 38 passing through the other side of the second intermediate insulating layer 36 is connected to the second electrode 35.

A third intermediate insulating layer 39 is formed on the first and second program nodes 37 and 38, and first and second program pads 40 and 41 pass through the third intermediate insulating layer 39 and are connected to the first and second program nodes 37 and 38.

A passivation layer 42 covering the first and second program pads 40 and 41 is formed, and the passivation layer 42 formed on the first and second program pads 40 and 41 is opened in order to apply the electric forcing to the first and second program pads 40 and 41.

In FIG. 11, since related devices such as transistors and contact plugs are formed on a lower portion of the ferroelectric capacitor FeC, the first intermediate insulating layer 32 is a multi-layer intermediate insulating layer and the first and second program-nodes 37 and 38 are a typical first metal line M1. In particular, the second program node 38 is a plate line connected to the second electrode 35 of the ferroelectric capacitor, and a barrier metal can be inserted thereinto in order to prevent the ferroelectric layer 34 from being degraded.

In FIG. 11, the ferroelectric capacitor is a metal-ferroelectric-metal (MFM) capacitor and the ferroelectric layer 34 is perovskite material or Bi-layered perovskite material, and requires a thin film having 10 Å to 5000 Å thick. In addition, an electric field applied to the capacitor increases under the same operating voltage according to the thin film.

For example, if a voltage higher than the operating voltage of the device is applied intentionally, a bread-down occurs at a high electric field. Once the break-down occurs, the capacitor does not perform its function any more and a current path is formed between respective electrodes.

In other words, if the voltage higher than the operating voltage of the device is applied to the first and second program pads 40 and 41, i.e., if the electric forcing is applied, the ferroelectric layer 34 is broken down and the current path is formed between the first electrode 33 and the second electrode 35, so that the redundancy cells are replaced with the repair redundancy cells.

If the repair operation is carried out through the above-described manner, it is possible to repair not only the fail bits existing within the main cells but also the redundancy cells that are not repairable. Therefore, the yield of the wafer is remarkably increased.

In FIG. 11, the ferroelectric capacitor can be a capacitor with a capacitor over bitline (COB) structure or a capacitor under bitline (CUB) structure. In addition, the ferroelectric capacitor can be a metal-insulator-metal (MIM) structure or a metal-insulator-silicon (MIS) structure, except a metal-ferroelectric-metal (MFM) structure.

In case of the MIM or MIS structure, the dielectric layer is formed of one selected from the group consisting of SiO₂, Si₃N₄, Ta₂O₅, TaON and combinations thereof, and the first and second electrodes are formed of one selected from the group consisting of TiN, RuTiN, IrTiN, Ir, IrO₂, Ru, RuO₂, Rh, RhO₂, Pt and combinations thereof.

Although the fail repair of the main cell having the fail bits is described in the above-described embodiments, the fail repair circuit in accordance with the present invention is also applicable to a method for replacing defective circuits in the process or design, except the repair of the redundancy cell.

As describe above, since it is possible to repair not only the fail bits existing within the main cells but also the redundancy cells that are not repairable, a time required to analyze failure can be reduced and the yield of the wafer can be remarkably increased.

While the present invention has been described with respect to certain preferred embodiments only, other modifications and variation may be made without departing from the spirit and scope of the present invention as set forth in the following claims.

What is claimed is:

1. In a semiconductor memory device including a memory cell array provided with a plurality of main cells and a redundancy circuit for replacing main cells having fail bits with redundancy cells, the redundancy circuit comprising:
a redundancy cell array including a plurality of redundancy cells to be substituted for the main cell having the fail bit; and
a repair redundancy cell array including a plurality of repair redundancy cells to be substituted for the redundancy cell having the fail bit, if the fail bit occurs in the redundancy cell substituted for the main cell having the fail bit.

2. The redundancy circuit as recited in claim 1, further comprising:
a repair logic unit for replacing a logic unit related to the memory cell array;
a first programming unit for connecting the redundancy cell array unit with the repair logic unit by programming to replace the main cell having the fail bit with the redundancy cell; and
a second programming unit for connecting the repair redundancy cell array with the repair logic unit by programming to replace the redundancy cell having the fail bit with the repair redundancy cell.

3. The redundancy circuit as recited in claim 2, wherein the first programming unit includes a plurality of fuses connected to respective rows/columns of the redundancy cell array.

4. The redundancy circuit as recited in claim 2, wherein the second programming unit includes a plurality of ferroelectric capacitors connected with respective rows/columns of the repair redundancy cell array, the repair redundancy cell array being connected with the repair logic unit by an electric forcing that causes a ferroelectric layer of the ferroelectric capacitor to be broken down.

5. The redundancy circuit: as recited in claim 4, further comprising:
a ferroelectric capacitor short control unit for shorting the plurality of ferroelectric capacitors contained in the second programming unit;
a plurality of switches for connecting the ferroelectric capacitor short control unit with the plurality of ferroelectric capacitors; and
an activation switch for connecting the rows/columns of the repair redundancy cell array with the ferroelectric capacitor short control unit.

6. In a semiconductor memory device including a memory cell array provided with a plurality of main cells, a fail repair method for replacing main cells having fail bits with redundancy cells, comprising the steps of:
replacing the main cell having the fail bit with the redundancy cell by a fuse cutting; and
if the fail bit occurs in the redundancy cell substituted for the main cell having the fail bit, replacing the redundancy cell having a fail bit with a repair redundancy cell by shorting two electrodes of a ferroelectric capacitor.

7. The fail repair method as recited in claim 6, wherein the shorting of the two electrodes of the ferroelectric capacitor is carried out by applying an electric forcing upon conditions that a ferroelectric layer of the ferroelectric capacitor is broken down.
